(19) United States
(12) Patent Application Publication
(10) Pub. No.: US 2009/0219768 A1
(43) Pub. Date: Sep. 3, 2009

(54) SEMICONDUCTOR MEMORY DEVICE HAVING SHARED BIT LINE SENSE AMPLIFIER SCHEME AND DRIVING METHOD THEREOF

(76) Inventors: Dong-Keun Kim, Kyoungki-do (KR); Chang-Ho Do, Kyoungki-do (KR)

Correspondence Address: MANNAVA & KANG, P.C., 11240 WAPLES MILL ROAD, Suite 300, FAIRFAX, VA, 22030, US

(21) Appl. No.: 12/466,180

(22) Filed: May 14, 2009

Related U.S. Application Data
(63) Continuation of application No. 11/477,324, filed on Jun. 30, 2006.

(30) Foreign Application Priority Data
Sep. 28, 2005 (KR) 2005-0090956
Dec. 29, 2005 (KR) 2005-0133985

(51) Int. Cl. G11C 7/00

(52) U.S. Cl. 365/189.11; 365/191; 365/205; 365/203

(57) ABSTRACT

A semiconductor memory device has a shared bit line sense amplifier. The semiconductor memory device includes: a bit line sense amplifier for amplifying data applied on bit line pair; an upper bit line disconnection unit for selectively disconnecting the bit line sense amplifier from bit line pair of an upper cell array in response to an upper bit line disconnection signal; a lower bit line disconnection unit for selectively disconnecting the bit line sense amplifier from bit line pair of a lower cell array in response to a lower bit line disconnection signal; an upper bit line equalization unit for equalizing the bit line pair of the upper cell array in response to the lower bit line disconnection signal; and a lower bit line equalization unit for equalizing the bit line pair of the lower cell array in response to the upper bit line disconnection signal.

### FIELD OF THE INVENTION

The present invention relates to a semiconductor memory device; and, more particularly, to a semiconductor memory device having a shared bit line sense amplifier scheme and a driving method thereof.

### DESCRIPTION OF RELATED ARTS

In most of semiconductor memory devices including DRAM, a bit line sense amplifier is used to sense a slight data signal applied on a bit line. The semiconductor memory device has a core region where a plurality of memory cells are arranged. In the core region, a memory cell array and the bit line sense amplifier array are repeatedly arranged in a column direction. That is, the memory cell arrays are arranged above and under the bit line sense amplifier. A shared bit line sense amplifier scheme is proposed which can maximize the efficiency of the bit line sense amplifier and reduce chip area. In the shared bit line sense amplifier scheme, a single bit line sense amplifier is commonly used by the upper and lower memory cell arrays.

FIG. 1 is a circuit diagram of a DRAM core having a shared bit line sense amplifier scheme.

Referring to FIG. 1, the bit lines sense amplifier includes two PMOS transistors connected between a pull-up voltage line RTO and bit line pair BL and BLB, and two NMOS transistors connected between a pull-down voltage line SB and bit line pair BL and BLB.

The bit line sense amplifier is shared by an upper cell array CELL ARRAY0 and a lower cell array CELL ARRAY1. A bit line disconnection unit, a bit line equalization unit, a bit line precharge unit, and a column selection unit are arranged between the bit line sense amplifier and the memory cell array.

Specifically, NMOS transistors M0 to M4 are disposed between the bit line sense amplifier and the cell array 0 block. The NMOS transistors M1 and M2 connect/disconnect an upper bit line pair BLU and BLBU to the bit line sense amplifier in response to an upper bit line disconnection signal BISH. The NMOS transistors M3 and M4 precharge the bit line pair BL and BLB to a bit line precharge voltage VBLP (generally Vdd/2) in response to a bit line equalization signal BLEQ. The NMOS transistor M0 equalizes the upper bit line pair BLU and BLBU in response to the bit line equalization signal BLEQ.

Also, NMOS transistors M5 to M7, and two NMOS transistors are disposed between the bit line sense amplifier and the cell array CELL ARRARY1. The NMOS transistors M5 and M6 connect/disconnect a lower bit line pair BLD and BLBD to the bit line sense amplifier in response to a lower bit line disconnection signal BISL. The NMOS transistor M7 equalizes the lower bit line pair BLD and BLBD in response to a bit line equalization signal BLEQ. Two NMOS transistors selectively connect the bit line pair BL and BLB to segment data bus pair SIO and SIOB in response to a column select signal CY.

FIG. 2 is a block diagram of a conventional bit line control circuit for generating the bit line disconnection signals BISH and BISL and the bit line equalization signal BLEQ.

Referring to FIG. 2, the conventional bit line control circuit includes a block controller 100, a bit line disconnection signal generator 110, and a bit line equalization signal generator 120. The block controller 100 receives a block address signal AX to generate block selection signals BS_0 and BS_1 corresponding to the memory cell arrays. The bit line disconnection signal generator 110 generates the bit line disconnection signals BISH and BISL in response to the block selection signals BS_0 and BS_1. The bit line equalization signal generator 120 generates the bit line equalization signal BLEQ in response to the block selection signals BS_0 and BS_1. The block controller 100 includes a plurality of block selection signal generators corresponding to the memory cell arrays.

Referring again to FIG. 1, the NMOS transistors M0 to M7 are turned on in a precharge state. When an active command is applied and the cell array 0 block is selected, the block selection signals BS_0 and BS_1 become logic level HIGH and logic level LOW, respectively.

In combination of the block selection signals BS_0 and BS_1, the upper bit line disconnection signal BISH maintains logic level HIGH so that the NMOS transistors M1 and M2 are turned on, and the lower bit line disconnection signal BISL is deactivated to logic level LOW so that the NMOS transistors M5 and M6 are turned off.

When the block selection signal BS_0 is activated to logic level HIGH, the bit line equalization signal BLEQ is deactivated to logic level LOW so that the NMOS transistors M0, M3, M4 and M7 are turned off.

As illustrated in FIG. 2, the bit line disconnection signal generator 110 and the bit line equalization signal generator 120 have to be separately provided. Because the separate signal lines have to be provided, a large number of metal lines are required. As described above, the bit line sense amplifiers are arranged in an array form, and a large number of bit line sense amplifier arrays are provided. Consequently, a chip area increases due to the bit line control circuit and the metal lines.

### SUMMARY OF THE INVENTION

It is, therefore, an object of the present invention to provide a semiconductor memory device having a shared bit line sense amplifier scheme and a driving method thereof, capable of preventing the increase of a chip area caused by a bit line control circuit and metal lines.

In accordance with an aspect of the present invention, there is provided a semiconductor memory device including: a bit line sense amplifier for amplifying data applied on a bit line pair; an upper bit line disconnection unit for selectively disconnecting the bit line sense amplifier from a bit line pair of an upper cell array in response to an upper bit line disconnection signal; a lower bit line disconnection unit for selectively disconnecting the bit line sense amplifier from a bit line pair of a lower cell array in response to a lower bit line disconnection signal; an upper bit line equalization unit for equalizing the bit line pair of the upper cell array in response to the lower bit line disconnection signal; and a lower bit line equalization unit for equalizing the bit line pair of the lower cell array in response to the upper bit line disconnection signal.

In accordance with another aspect of the present invention, there is provided a method for driving a semiconductor memory device including: amplifying data applied on a bit line pair; selectively disconnecting a bit line sense amplifier from a bit line pair of an upper cell array in response to an upper bit line disconnection signal; selectively disconnecting the bit line sense amplifier from a bit line pair of a lower cell array in response to a lower bit line disconnection signal; equalizing the bit line pair of the upper cell array in response to the lower bit line disconnection signal; and equalizing the bit line pair of the lower cell array in response to the upper bit line disconnection signal.

### BRIEF DESCRIPTION OF THE DRAWINGS

The above and other objects and features of the present invention will become apparent from the following description of preferred embodiments given in conjunction with the accompanying drawings, in which:

FIG. 1 is a circuit diagram of a DRAM core having a shared bit line sense amplifier scheme;

FIG. 2 is a block diagram of a conventional bit line control circuit for generating a bit line disconnection signal and a bit line equalization signal;

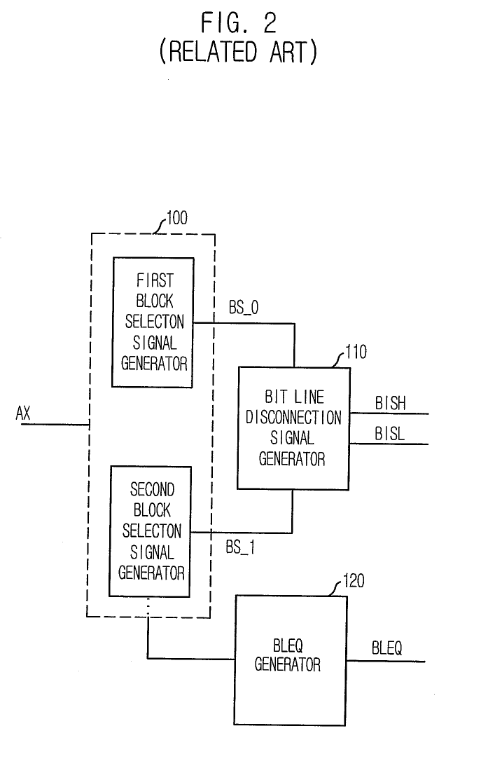

FIG. 3 is a circuit diagram of a DRAM core in accordance with an embodiment of the present invention;

FIG. 4 is a circuit diagram of a bit line control circuit for generating an upper bit line disconnection signal and a lower bit line disconnection signal in FIG. 3; and

FIGS. 5A to 5C show a circuit diagram of a bit line equalizer of FIG. 3.

### DETAILED DESCRIPTION OF THE INVENTION

Hereinafter, a semiconductor memory device having a shared bit line sense amplifier scheme and a driving method thereof in accordance with exemplary embodiments of the present invention will be described in detail with reference to the accompanying drawings.

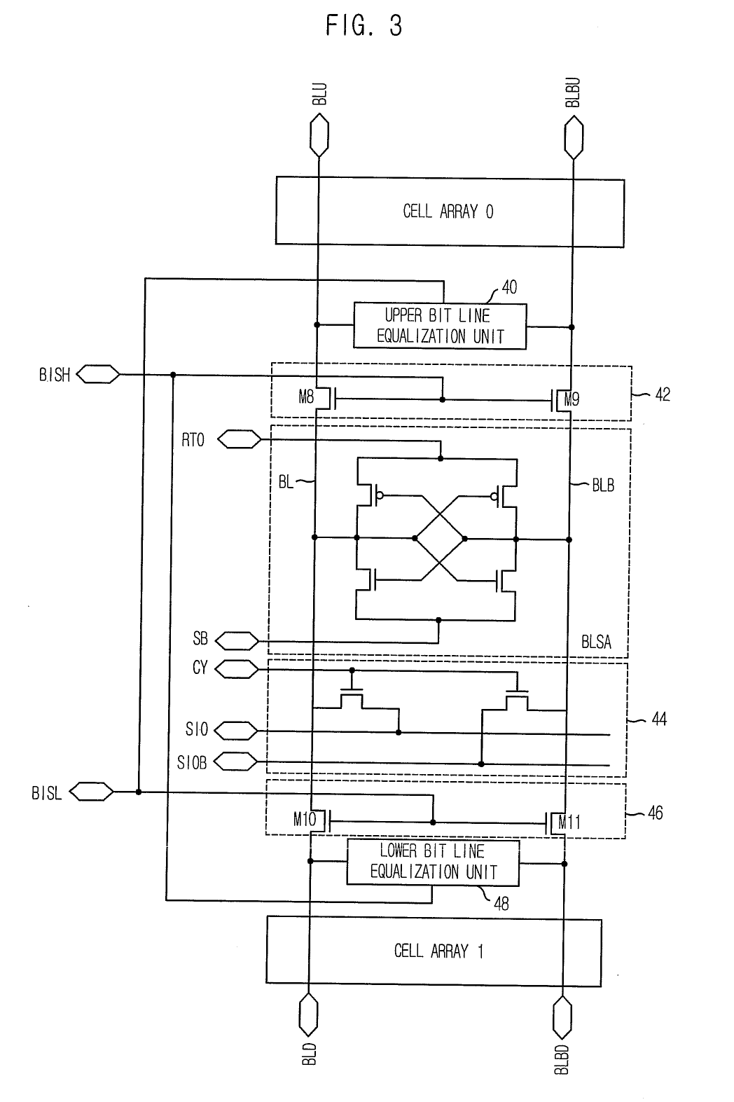

FIG. 3 is a circuit diagram of a DRAM core in accordance with an embodiment of the present invention.

Referring to FIG. 3, the DRAM includes a bit line sense amplifier, an upper bit line disconnection unit 42, a lower bit line disconnection unit 46, an upper bit line equalization unit 40, and a lower bit line equalization unit 48. The bit line sense amplifier amplifies data applied on the bit line pair connected to an upper cell array CELL ARRAY0 or a lower cell array CELL ARRARY1. The upper bit line disconnection unit 42 selectively disconnects the bit line sense amplifier from the bit line pair BLU and BLBU of the cell array CELL ARRAY0 in response to an upper bit line disconnection signal BISH. The lower bit line disconnection unit 46 selectively disconnects the bit line sense amplifier from the bit line pair BLD and BLBD of the cell array CELL ARRARY1 in response to a lower bit line disconnection signal BISL. The upper bit line equalization unit 40 equalizes the bit line pair BLU and BLBU of the cell array CELL ARRAY0 in response to the lower bit line disconnection signal BISL. The lower bit line equalization unit 48 equalizes the bit line pair BLD and BLBD of the cell array CELL ARRARY1 in response to the upper bit line disconnection signal BISH.

A column select unit 44 is disposed between the upper bit line disconnection unit 42 and the lower bit line disconnection unit 46. The column select unit 44 selectively connects a bit line pair BL and BLB and a segment data bus pair SIO and SIOB in response to the column select signal CY.

The upper bit line disconnection unit 42 includes NMOS transistors M8 and M9 having gates receiving the upper bit line disconnection signal BISH and connects/disconnects the upper bit line pair BLU and BLBU and the bit line sense amplifier.

In addition, the lower bit line disconnection unit 46 includes NMOS transistors M10 and M11 having gates receiving the lower bit line disconnection signal BISL and connects/disconnects the lower bit line pair BLD and BLBD and the bit line sense amplifier.

The bit line sense amplifier includes two PMOS transistors connected between a pull-up voltage line (RTO line) and the bit line pair BL and BLB, and two NMOS transistors connected between a pull-down voltage line SB and the bit line pair BL and BLB. The column select unit 44 includes two NMOS transistors having gates receiving the column select signal CY and selectively connects the bit line pair BL and BLB and the segment data bus pair SIO and SIOB.

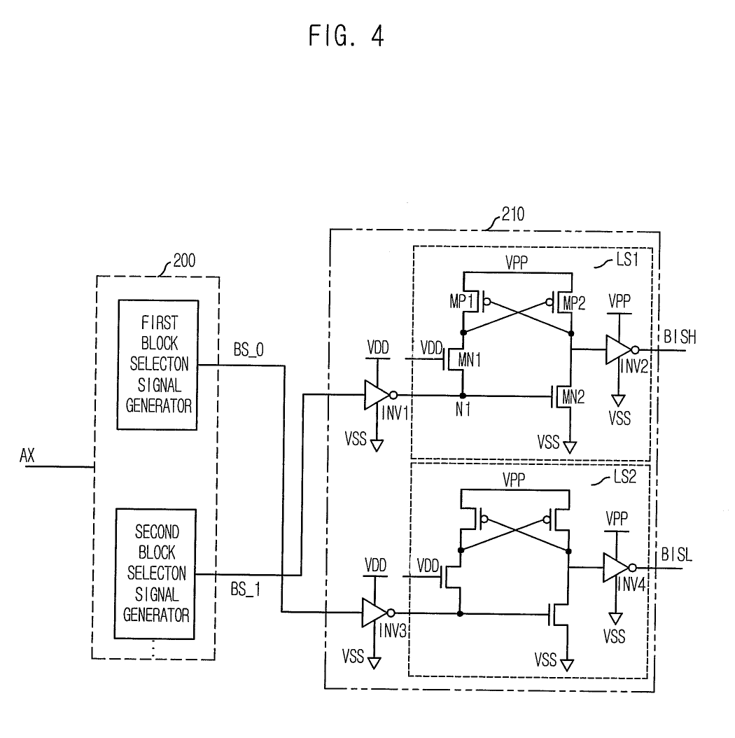

FIG. 4 is a circuit diagram of a bit line control circuit for generating the upper bit line disconnection signal and the lower bit line disconnection signal in FIG. 3.

Referring to FIG. 4, the bit line control circuit includes a block controller 200 and a bit line disconnection signal generator 210. The block controller 200 receives a block address signal AX to generate block selection signals BS_0 and BS_1 corresponding to the memory cell arrays. The bit line disconnection signal generator 210 generates the bit line disconnection signals BISH and BISL in response to the block selection signals BS_0 and BS_1.

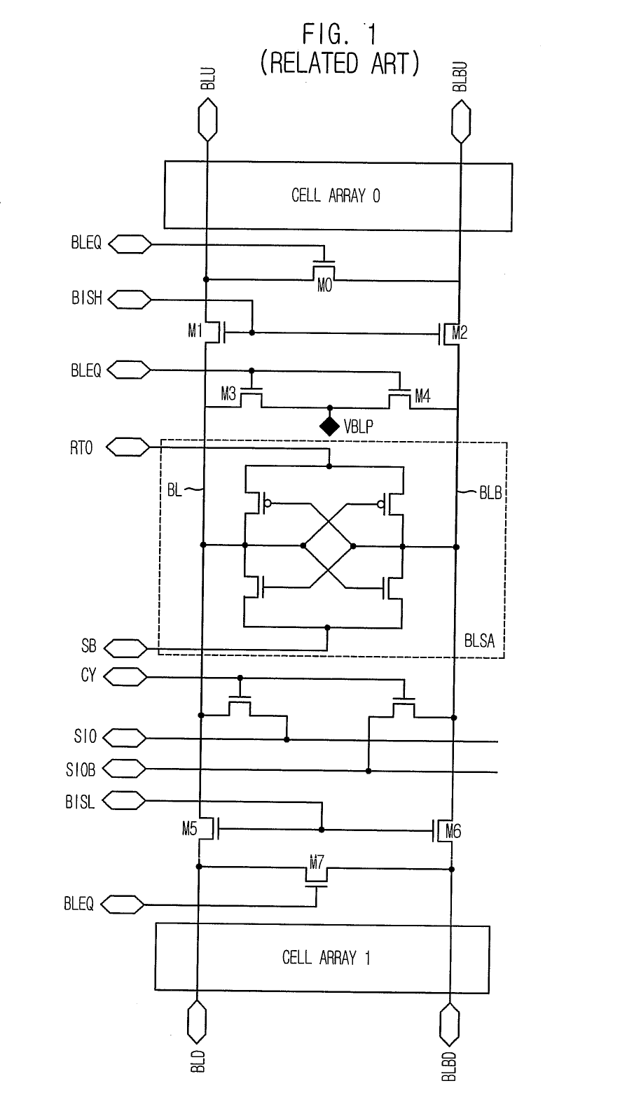

Compared with the related art shown FIG. 1, the bit line control circuit of the present invention does not include the bit line equalization signal generator 120. The reason for this is that the bit line equalization units 40 and 48 are controlled by the bit line disconnection signals BISH and BISL, instead of the bit line equalization signal BLEQ.

The block controller 200 includes a plurality of block selection signal generators corresponding to the respective memory cell arrays.

The bit line disconnection signal generator 210 includes an upper bit line disconnection signal generator for generating the upper bit line disconnection signal BISH in response to the lower block selection signal BS_1, and a lower bit line disconnection signal generator for generating the lower bit line disconnection signal BISL in response to the upper block selection signal BS_0.

The upper bit line disconnection signal generator includes an inverter INV1 receiving the lower block selection signal BS_1 and a level shifter LS1 for increasing an activation level of an output signal of the inverter INV1, and the lower bit line disconnection signal generator includes an inverter INV3 receiving the upper block selection signal BS_0 and a level shifter LS2 for increasing an activation level of an output signal of the inverter INV3.

In the level shifter LS1, two PMOS transistors MP1 and MP2 have sources connected to a high voltage terminal VPP and gates and drains cross-connected together. An NMOS transistor MN1 has a drain connected to the drain of the PMOS transistor MP1, a source connected to an input terminal N1, and a gate receiving a power supply voltage VDD. An NMOS transistor MN2 has a drain connected to the drain of the PMOS transistor MP2, a source connected to a ground terminal VSS, and a gate connected to the input terminal N1. An inverter INV2 is connected to the drain of the PMOS transistor MP2.

The level shifters LS1 and LS2 are implemented using well-known circuits. The reason why the bit line disconnection signals BISH and BISL are generated using the level shifters LS1 and LS2 is that the bit line disconnection transistors are driven at the high voltage VPP higher than the power supply voltage VDD, considering the loss of threshold voltage.

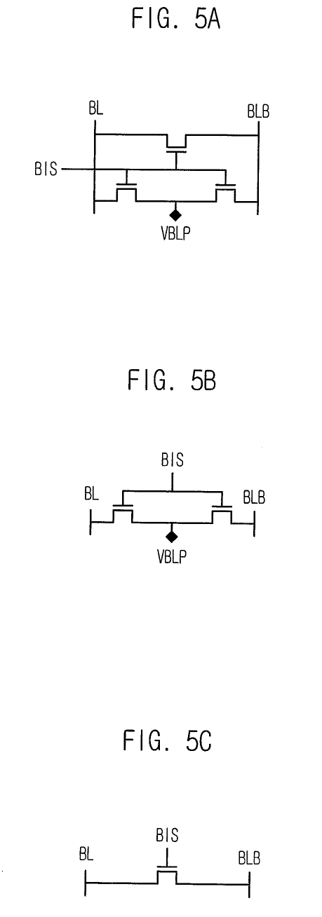

FIGS. 5A to 5C show a circuit diagram of the bit line equalization units 40 and 48 of FIG. 3, respectively.

Referring to FIG. 5A, the bit line equalization units 40 and 48 include an NMOS transistor having a gate receiving a bit line disconnection signal BIS and connected between the bit line pair BL and BLB, and two NMOS transistors having gates receiving the bit line disconnection signal BIS and connected between the bit line precharge voltage VBLP (generally VBPL=Vdd/2) and the bit line pair BL and BLB.

Referring to FIG. 5B, the bit line equalization units 40 and 48 include two NMOS transistors having gates receiving the bit line disconnection signal BIS and connected between the bit line precharge voltage VBLP (generally Vdd/2) and the bit line pair BL and BLB.

Referring to FIG. 5C, the bit line equalization unit 40 and 48 include an MOS transistor having a gate receiving the bit line disconnection signal BIS and connected between the bit line pair BL and BLB.

In FIGS. 5A and 5B, the bit line precharge voltage VBLP is applied to both the upper bit line equalization unit 40 and the lower bit line equalization unit 48. On the contrary, in FIG. 5(C), the bit line precharge voltage VBLP is applied to one of the upper bit line equalization unit 40 and the lower bit line equalization unit 48.

Because the upper bit line disconnection signal BISH and the lower bit line disconnection signal BISL are in logic level HIGH in the precharge state, the NMOS transistors M8 to M11 are turned on. All the NMOS transistors of the bit line equalization units 40 and 48 are also turned on.

When an active command is applied and the cell array CELL ARRAY0 is selected, the block selection signals BS_0 and BS_1 become logic level HIGH and logic level LOW, respectively. In combination of the block selection signals BS_0 and BS_1, the upper bit line disconnection signal BISH maintains logic level HIGH. Therefore, the NMOS transistors M8 and M9 of the upper bit line disconnection unit 42 and all NMOS transistors of the lower bit line equalization unit 48 are also turned on. Meanwhile, the lower bit line disconnection signal BISL is deactivated to logic level LOW, so that the NMOS transistors M10 and M11 of the lower bit line disconnection unit 46 and all NMOS transistors of the upper bit line equalization unit 40 are turned off.

In contrast, when the cell array CELL ARRARY1 is selected, the block selection signals BS_0 and BS_1 become logic level LOW and logic level HIGH, respectively. Therefore, the lower bit line disconnection signal BISL maintains logic level HIGH. Therefore, the NMOS transistors M10 and M11 of the lower bit line disconnection unit 46 and all NMOS transistors of the upper bit line equalization unit 40 are also turned on. Meanwhile, the upper bit line disconnection signal BISH is deactivated to logic level LOW, so that the NMOS transistors M8 and M9 of the upper bit line disconnection unit 42 and all NMOS transistors of the lower bit line equalization unit 48 are turned off.

As described above, even if the bit line equalization unit is controlled using the bit line disconnection signals, the memory device can be operated normally. That is, an additional circuit for generating the bit line equalization signal is not needed.

In accordance with the present invention, the bit line control circuit can be simplified, thus reducing the memory chip area.

The present application contains subject matter related to Korean patent application No. 2005-90956 and 2005-133985, filed in the Korean Patent Office on Sep. 29, 2005 and Dec. 29, 2005, respectively, the entire contents of which are incorporated herein by reference.

While the present invention has been described with respect to certain preferred embodiments, it will be apparent to those skilled in the art that various changes and modifications may be made without departing from the scope of the invention as defined in the following claims.

1-13. (canceled)

14. A semiconductor memory device comprising:
a lower bit line disconnection signal generator configured to generate a lower bit line disconnection signal in response to a first block selection signal corresponding to an upper cell array;
an upper bit line disconnection signal generator configured to generate an upper bit line disconnection signal in response to a second block selection signal corresponding to a lower cell array;
a bit line sense amplifier configured to amplify data applied on a bit line pair;
an upper bit line disconnection unit configured to selectively disconnect the bit line sense amplifier from a bit line pair of the upper cell array in response to the upper bit line disconnection signal;
a lower bit line disconnection unit configured to selectively disconnect the bit line sense amplifier from a bit line pair of a lower cell array in response to a lower bit line disconnection signal;
an upper bit line equalization unit configured to receive the lower bit line disconnection signal and to equalize the bit line pair of the upper cell array in response to the lower bit line disconnection signal; and
a lower bit line equalization unit configured to receive the upper bit line disconnection signal and to equalize the bit line pair of the lower cell array in response to the upper bit line disconnection signal,
wherein the bit line sense amplifier, the upper bit line disconnection unit, the lower bit line disconnection unit, the upper bit line equalization unit, and the lower bit line equalization unit are arranged in a cell area,
wherein the lower bit disconnection signal is directly inputted to the upper bit line equalization unit and the lower bit line disconnection unit via a first local line, and the upper bit line disconnection signal is directly inputted to the upper bit line disconnection unit and the lower bit line equalization unit via a second local line.

15. The semiconductor memory device of claim 14, further comprising a column select unit for selectively connecting the bit line pair and segment data bus pair in response to a column select signal.

16. The semiconductor memory device of claim 14, wherein the upper bit line disconnection unit includes first and second NMOS transistors having gates receiving the upper bit line disconnection signal and connecting/disconnecting the bit line pair of the upper cell array and the bit line sense amplifier.

17. The semiconductor memory device of claim 16, wherein the lower bit line disconnection unit includes third and fourth NMOS transistors having gates receiving the lower bit line disconnection signal and connecting/disconnecting the bit line pair of the lower cell array and the bit line sense amplifier.

18. The semiconductor memory device of claim 14, wherein the lower bit line disconnection signal generator includes:
a first inverter for inverting the first block selection signal; and
a first level shifter for increasing an activation level of an output signal of the first inverter.

19. The semiconductor memory device of claim 18, wherein the upper bit line disconnection signal generator includes:
a second inverter for inverting the second block selection signal; and
a second level shifter for increasing an activation level of an output signal of the second inverter.

20. The semiconductor memory device of claim 19, wherein each of the first and second level shifters includes:
first and second PMOS transistors having sources connected to a high voltage terminal (VPP) and a gate and a drain cross-connected together;
a first NMOS transistor having a drain connected to the drain of the first PMOS transistor, a source connected to an input terminal, and a gate receiving a power supply voltage;
a second NMOS transistor having a drain connected to the drain of the second PMOS transistor, a source connected to a ground terminal, and a gate connected to the input terminal; and
a third inverter connected to the drain of the second PMOS transistor.

21. The semiconductor memory device of claim 14, wherein the upper bit line equalization unit includes a first NMOS transistor having a gate receiving the lower bit line disconnection signal and connected to the bit line pair of the upper cell array.

22. The semiconductor memory device of claim 14, wherein the lower bit line equalization unit includes a first NMOS transistor having a gate receiving the upper bit line disconnection signal and connected to the bit line pair of the lower cell array.

23. The semiconductor memory device of claim 14, wherein the upper/lower bit line equalization units include first and second NMOS transistors having gates receiving the lower/upper bit line disconnection signal and connected between a bit line precharge voltage and the bit line pair of the upper/lower cell arrays.

24. The semiconductor memory device of claim 14, wherein the upper/lower bit line equalization units include:
a first NMOS transistor having a gate receiving the lower/upper bit line disconnection signal and connected between the bit line pair of the upper/lower cell arrays; and
second and third NMOS transistors having gates receiving the lower/upper bit line disconnection signal and connected between a bit line precharge voltage and the bit line pair of the upper/lower cell arrays.

25. A semiconductor memory device comprising:
an upper bit line disconnection unit configured to receive an upper bit line disconnection signal generated from an upper bit line disconnection signal generator and to selectively disconnect a bit line sense amplifier from a pair of bit lines of the upper cell array in response to the upper bit line disconnection signal;
an upper bit line equalization unit configured to receive a lower bit line disconnection signal generated from a lower bit line disconnection signal generator and to equalize the pair of bit lines of the upper cell array in response to the lower bit line disconnection signal;
a lower bit line disconnection unit configured to receive the lower bit line disconnection signal and to selectively disconnect the bit line sense amplifier from a pair of bit lines of a lower cell array in response to the lower bit line disconnection signal; and
a lower bit line equalization unit configured to receive the upper bit line disconnection signal and to equalize the pair of bit lines of the lower cell array in response to the upper bit line disconnection signal,
wherein the upper bit line disconnection signal is directly provided to the upper bit line disconnection unit and the lower bit line equalization unit, and the lower bit line disconnection signal is directly provided to the lower bit line disconnection unit and the upper bit line equalization unit.

26. The semiconductor memory device of claim 25, wherein the lower bit line disconnection signal generator is configured to generate the lower bit line disconnection signal in response to a first block selection signal corresponding to the upper cell array.

27. The semiconductor memory device of claim 25, wherein the upper bit line disconnection signal generator is configured to generate the upper bit line disconnection signal in response to a second block selection signal corresponding to the lower cell array.
